(19) United States
(12) Patent Application Publication
(10) Pub. No.: US 2026/0118409 A1
(43) Pub. Date: Apr. 30, 2026

(54) SYSTEM AND METHOD FOR VACUUM-ASSISTED MECHANICAL BOARD TO BOARD LATCHING INTERFACE SYSTEM FOR ATE TEST CELLS

(71) Applicant: INTEST EMS, LLC, Mount Laurel, NJ (US)

(72) Inventors: Jason FONG, Mount Laurel, NJ (US); Baltazar S. CARRASCO, Fremont, CA (US)

(21) Appl. No.: 19/371,196

(22) Filed: Oct. 28, 2025

Related U.S. Application Data
(60) Provisional application No. 63/713,861, filed on Oct. 30, 2024.

(51) Int. Cl. G01R 31/28

(52) U.S. Cl. CPC G01R 31/2844; G01R 31/2834; G01R 31/2889

(57) ABSTRACT

A hybrid vacuum-assisted mechanical latch system for a semiconductor automatic test equipment (ATE) system. The system applies a temporary vacuum from a test interface assembly (TIA), having spring-loaded electrical contacts, to a probe interface board assembly (PIBA) on a first TIA side and to a probe card assembly (PCA) on a second TIA side after the PIBA and PCA are placed into contact with the TIA. A displaceable latch plate having plural projections on a first edge and plural projections on a second edge is included on the TIA. The PIBA side in contact with the TIA has corresponding plural receptacles as does the PCA side in contact with the TIA. When vacuum is applied, the plural projections seat themselves within the plural receptacles and then the latch plate is displaced, thereby locking the PIBA and PCA in a stable electrical contact where spring forces are 700 lbf-2200 lbf.

This non-provisional application claims the benefit under 35 U.S.C. § 119 (e) of Application Ser. No. 63/713,861 filed on Oct. 30, 2024 and whose entire disclosure is incorporated by reference herein.

### BACKGROUND OF THE INVENTION

### 1. Field of Invention

This invention relates to the automated test equipment (ATE) used for semiconductor products.

### 2. Description of Related Art

Existing systems that engage a spring-probe based electrical Test Interfaces between a Probe-Interface-Board (PIB) and a Probe Card (PC), a PIB to mezzanine PIB, and other PIB to auxiliary board interfaces, are mostly mechanical in nature or sometimes purely vacuum-based. These systems must overcome the spring force of the Test Interface (utilizing “Pogo pins” that are spring-loaded pins which act as an electrical connector mechanism known for their durability and ability to provide an electrical connection that is resilient to mechanical shock and vibration) that can range between 700 lbf-2200 lbf and maintain critical mechanical stability required for ATE testing interfaces. Thus, these systems must provide clamping capacity in that same range to overcome the spring force. Larger forces generally cannot be accommodated due to size constraints and unwanted mechanical deflection caused by the spring force during dynamic compression events. Thus, there remains a need for system and method of bringing the PIB into a stable electrical contact with the PC by providing a compression force that overcomes the spring forces in the range of 700 lbf-2200 lbf while eliminating or otherwise minimizing deflections of the PC. The system and method of the present invention provide a solution to these issues.

All references cited herein are incorporated herein by reference in their entireties.

### BRIEF SUMMARY OF THE INVENTION

A hybrid vacuum-assisted mechanical latch system for use in automatic test equipment (ATE) for semiconductor wafers is disclosed. A test interface assembly is used therein and includes spring-loaded electrical contacts that present spring forces that must be overcome in order to achieve stable electrical contact between a probe interface board assembly and a probe card assembly while minimizing or eliminating deflections of portions of the probe card assembly. The system comprises: a probe interface board assembly (PIBA) having a plurality of strike bars on a first side of the PIBA, each strike bar having a first plurality of receptacles configured for receiving a first plurality of projections therein; a probe card assembly (PCA) having a second plurality of strike bars on a first side of the PCA, each strike bar having a second plurality of receptacles configured for receiving a second plurality of projections therein; a test interface assembly (TIA) having a displaceable latch plate therein, the latch plate comprising the first plurality of projections on an upper edge and the second plurality of projections on a lower edge, opposite the upper edge; and a vacuum system, in fluid communication with the TIA, for temporarily applying a vacuum to position the first plurality of projections within the first plurality of receptacles and applying the temporary vacuum to the PCA to position the second plurality of projections within the second plurality of receptacles, and wherein the latch plate is displaced to lock the first plurality of projections within the first plurality of receptacles and to lock the second plurality of projections within the second plurality of receptacles such that the PIBA and the PCA are placed into a fixed position with stable electrical contact, by providing a compression force (e.g., in the range of 700 lbf-2200 lbf) that overcomes the spring forces, thereby permitting non-vibrational operation for ATE testing once the vacuum is removed.

A method for supporting automatic test equipment (ATE) testing of semiconductor wafers wherein spring-loaded electrical contacts used in a testing interface assembly is disclosed. The spring-loaded electrical contacts present spring forces that must be overcome in order to achieve stable electrical contact between a probe interface board assembly and a probe card assembly while minimizing or eliminating deflections of portions of the probe card assembly. The method comprises: providing a probe interface board assembly (PIBA) having a plurality of strike bars on a first side of the PIBA, each strike bar having a first plurality of receptacles configured for receiving a first plurality of projections therein; providing a probe card assembly (PCA) having a second plurality of strike bars on a first side of the PCA, each strike bar having a second plurality of receptacles configured for receiving a second plurality of projections therein; providing a test interface assembly (TIA) having a displaceable latch plate therein, the latch plate comprising the first plurality of projections on an upper edge and the second plurality of projections on a lower edge, opposite the upper edge; positioning the PIBA into contact with a first side of the TIA and positioning the PCA into contact with a second side, opposite the first side, of the TIA; temporarily applying a vacuum from first side of the TIA to the PIBA to position the first plurality of projections within the first plurality of receptacles and also temporarily applying the vacuum from the second side of the TIA to the PCA to position the second plurality of projections within the second plurality of receptacles; displacing the latch plate to lock the first plurality of projections within the first plurality of receptacles and to lock the second plurality of projections within the second plurality of receptacles such that the PIBA and the PCA are placed into a fixed position by providing a compression force (e.g., 700 lbf-2200 lbf) that overcomes the spring forces; and removing the vacuum to thereby permit non-vibrational operation for ATE testing.

### BRIEF DESCRIPTION OF SEVERAL VIEWS OF THE DRAWINGS

The invention will be described in conjunction with the following drawings in which like reference numerals designate like elements and wherein:

FIG. 1 depicts the present invention of a hybrid vacuum-assisted mechanical latch system for use in automatic test equipment (ATE) for semiconductor wafers;

FIG. 2 is an exploded cross-sectional view of the present invention showing the Probe-Interface-Board Assembly (PIBA) over the Test Interface Assembly (TIA) and the Probe Card Assembly (PCA) positioned underneath and including the displaceable latch plate;

FIG. 3 is a similar view to FIG. 2 but in a non-exploded view;

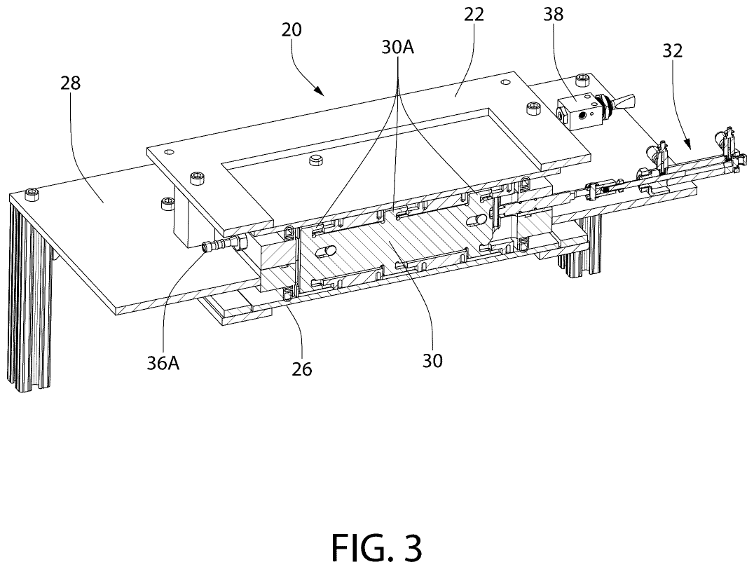

FIG. 4 depicts the invention but with the PIBA removed, thereby exposing the Pogo segment in the TIA;

FIG. 5 is an exploded cross-sectional plan view of the present invention showing the latch plate with L-shaped projections on the top and bottom for interfacing with corresponding receptacles in strike on the PIBA and PCA;

FIG. 6A shows the first step of the process whereby the PIBA is positioned in proximity to the TIA;

FIG. 6B shows the second step of the process whereby the PCA is moved upward to be in proximity of the Test Interface Assembly;

FIG. 6C shows the third step of the process whereby the vacuum assist is applied to bring the PIBA and the PCA into electrical contact with respective sides of the TIA while aligning the hooks of the latch plate with respective receptacles in the strike bars;

FIG. 6D shows the fourth step of the process where the fixed-latch mechanism is activated to displace the Latch plate to the right, as shown by the arrow, to hold the PIBA and the PCA into a fixed position in the TIA; and

FIG. 6E shows the PIBA and the PCA in the fixed position.

### DETAILED DESCRIPTION OF THE INVENTION

As mentioned previously, semiconductor wafer testing is conducted at an automatic test equipment (ATE) station which includes a Test Interface Assembly. By way of example only, the ATE test system may be an UltraFLEX+ testing system sold by Teradyne of North Reading MA. It should be understood that other test systems could be used and that the UltraFLEX+ test system is simply being cited by way of example. However, as also mentioned previously, all of these test systems suffer from bringing the PIB into a stable electrical contact with the PC where spring forces in the range of 700 lbf-2200 lbf are present and wherein unwanted deflections of the PC occur.

The invention 20 of the present application solves these problems by introducing a sequenced hybrid vacuum and mechanical system able to compress spring-pin based Test Interfaces by providing a clamping capacity (also referred to as a “compression force”) that overcomes the spring force in the range of 700 lbf-2200 lbf. The system 20 utilizes vacuum to assist in the compression force, then uses a secondary latching system to hold the boards to a fixed position. This approach provides two advantages. First, the latching mechanism bears all the load needed to hold the boards together, reducing mechanical deflection to the localized area around the pogo modules. Second, it allows the vacuum to be removed, eliminating the potential of vibration/movement caused by variations in the vacuum force.

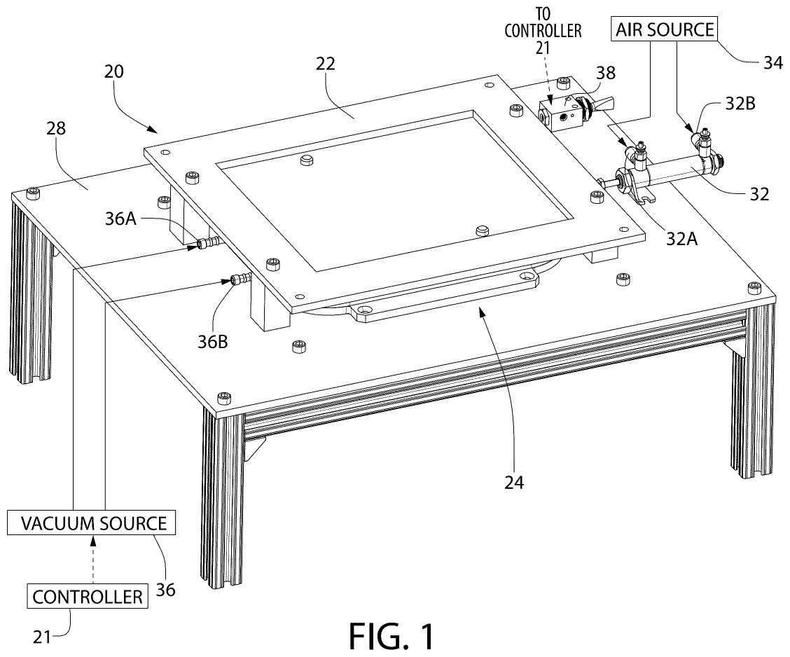

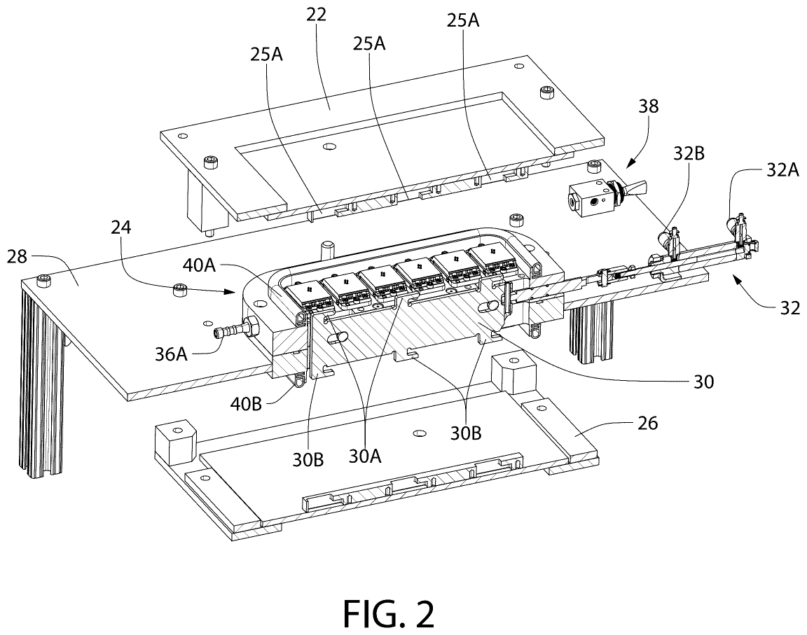

FIG. 1 depicts the present invention 20 for use at an ATE semiconductor test station (not shown). The present invention 20 comprises a Probe-Interface-Board Assembly (PIBA) 22 coupled to a Test Interface Assembly (TIA) 24 secured to a Probe Headplate (PH) 28 along with a Probe Card Assembly (PCA) 26 (see FIG. 2) underneath the PH 28. As will be discussed in detail later, a latch plate 30 (FIG. 2) is driven by an actuator 32 (e.g., an air cylinder actuator) that is coupled to power source 34 (e.g., air source). Where the actuator 32 is an air cylinder actuator, a pair of valves 32A/32B is provided to form a double-acting cylinder. As such, whereas pressurizing first valve 32A while exhausting second valve 32B retracts the actuator piston (inward towards the TIA 24), pressurizing second valve 32B and exhausting first valve 32A extends the actuator piston (outward away from the TIA 24). Activation of the actuator 32 is effected by a switch 38.

On the opposite side of the invention 20, are a pair of couplings 36A/36B to which the vacuum source 34 is coupled for applying a vacuum therethrough.

By way of example only, the air cylinder actuator 32 requires a small force to operate. Movement of the latch plate 30 (as is discussed below) is only resisted by an O-ring (not shown) along the air cylinder actuator rod that prevents the vacuum form leaking. Movement of the latch plate 30 requires approximately <15 lbs of force for a 7/16 inch bore size cylinder at 100 psi of inlet pressure.

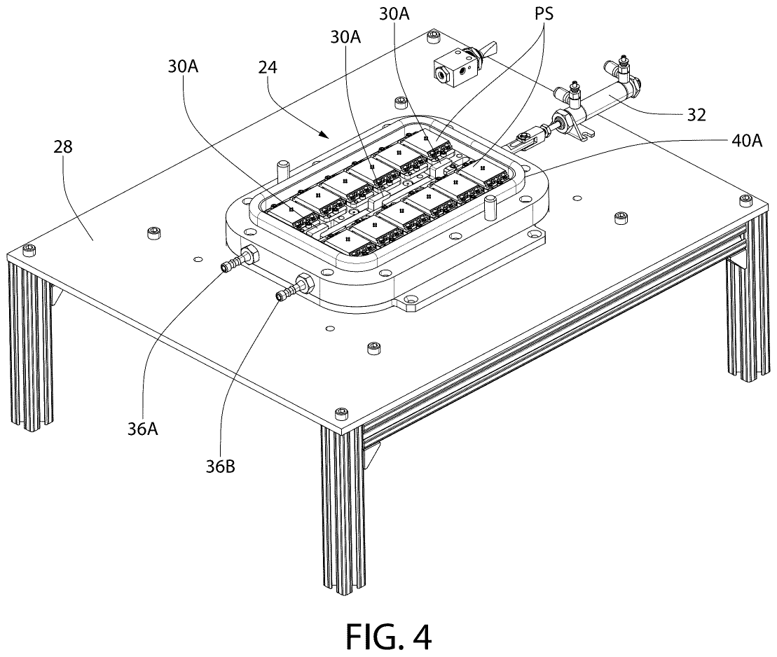

As shown most clearly in FIG. 4, the TIA 24 features a scalable segment comprising twelve Pogo modules, where the ratio of surface area to Pogo segments PS remains constant as additional segments are introduced. Each segment is paired with a single latching mechanism and contains 2,904 pogo pins. This modular arrangement can be replicated up to eight times, resulting in a total of 23,232 pogo pins that collectively exert a separation force exceeding 2,100 lbf between the PIBA 22 and PCA 26. To address the mechanical challenges posed by this high pin count and resulting load, the invention 20 incorporates a vacuum assist and latch mechanism. This system (1) stabilizes engagement between the PIBA 22, PCA 26 and TIA 24; (2) eliminates wafer movement caused by vacuum pressure fluctuations by disengaging the vacuum post-assist, (3) localizes deflection of the PCA 26 during testing, and (4) counteracts the substantial loading forces within a constrained environment.

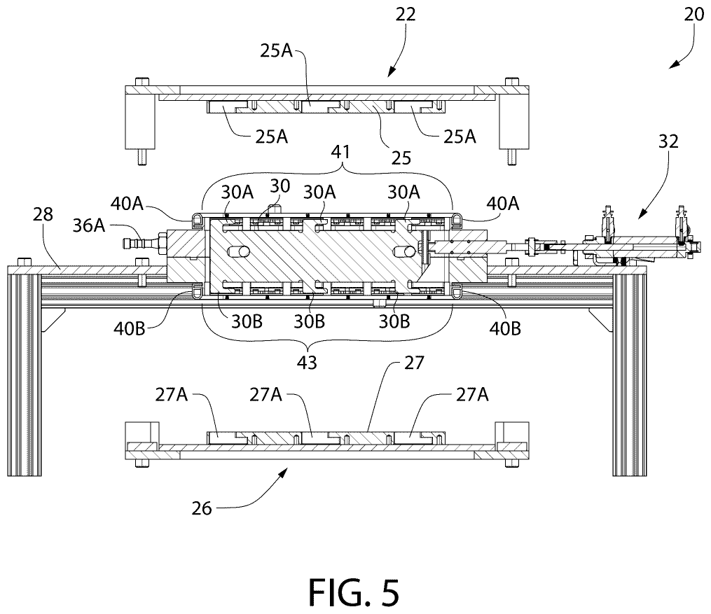

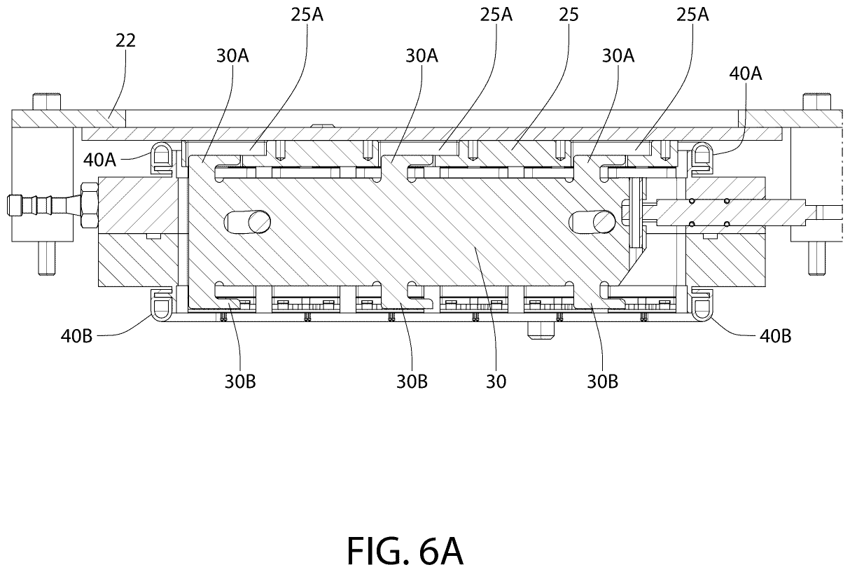

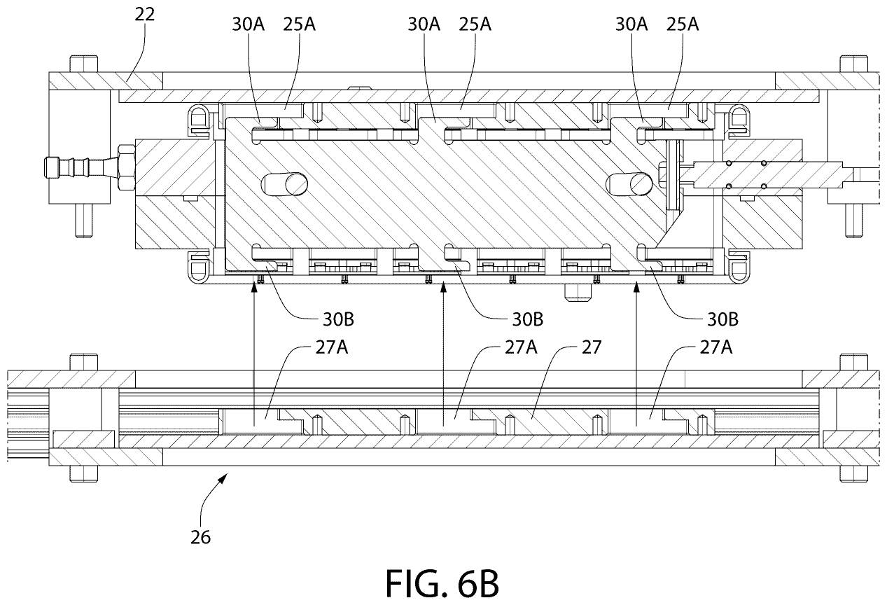

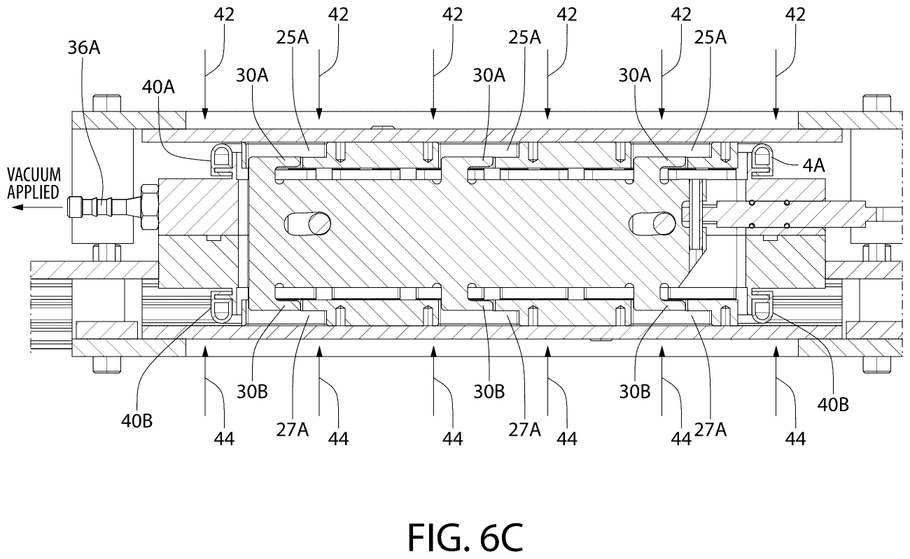

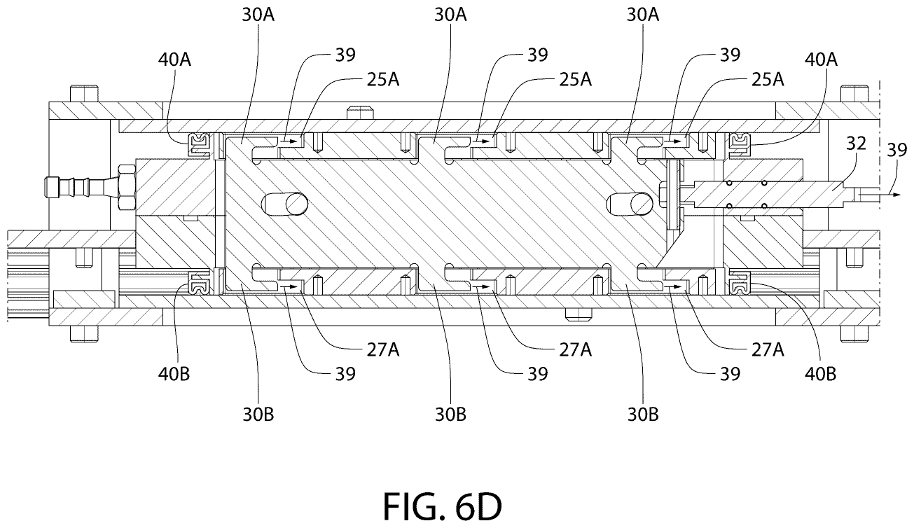

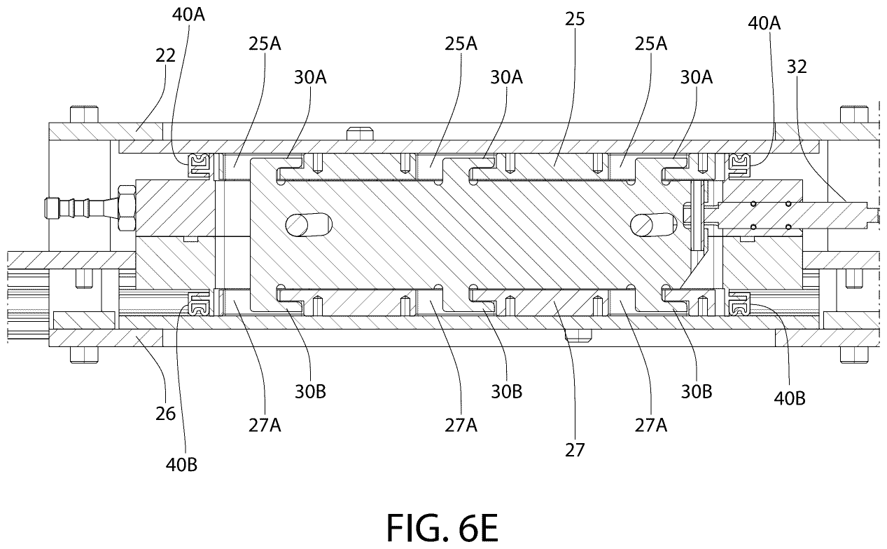

As can be seen most clearly in FIGS. 2 and 5, the latch plate 30 comprises a plurality of L-shaped projections 30A on its top surface and a plurality of L-shaped projections 30B on its bottom surface. These are configured to be inserted and then slid within respective receptacles in the PIBA 22 and the PCA 26 to lock PIBA 22 and PCA 24 against the TIA 24 to form the stable electrical contact while eliminating or minimizing deflections of the PCA 24. In particular, the PIBA 22 has a plurality of strike bars (only one 25 of which is shown) and the PCA 24 also comprises a plurality of strike bars (only one 27 of which is shown). Each strike bar 25 comprises a plurality of L-shaped receptacles 25A and each strike bar 27 comprises a plurality of L-shaped receptacles 27A. Thus, once the projections 30A/30B are aligned with their corresponding receptacles 25A/27A, the projections 30A/30B are positioned within the receptacles 25A/27A and then the air cylinder actuator 32 is activated to drive the projections 30A/30B in the direction 39 (FIG. 6D) to establish the stabilized electrical contact with no or minimum deflections.

As mentioned previously, the hybrid configuration of the present invention 20 first activates, but before that occurs the vacuum system is used to bring the PIBA 22 and PCA 26 into close contact with the TIA 24. In this hybrid vacuum assisted system, an air-tight vacuum zone is created by the presence of vacuum seals 40A/40B on both the PIBA 22 facing side of the TIA 24 as well as the PCA 26 facing side of the TIA 24 (see FIGS. 2 and 5). These seals 40A/40B are positioned to encompass the full spring-pin module section (i.e., the Pogo segment PS), covering an area where the available vacuum pressure can exert enough force to overcome the spring module's spring force. The seal must maintain an airtight seal over the movement needed to (1) allow the latch plate 30 to engage the strike bars 25/27 on both board assemblies, and (2) compress the spring-pin modules to establish a reliable electrical connection. In particular, when the vacuum source 36 is activated, the vacuum is applied through the couplings 36A/36B and directly through an aperture (not shown) into a center opened area in the TIA 24. When the vacuum source 36 is on, the region 41 (i.e., area within the interior of the vacuum seal 40A) defines the area of vacuum pressure that is applied to a center region of the PIBA 22. This means that if the PIBA 22 is in contact with the vacuum seal 40A, the corresponding surface area of the interior of the PIBA 22 is acted on by the vacuum pressure. As the vacuum pressure increases in magnitude, the seal 40A compresses in height. See the compression of vacuum seal 40A in FIGS. 6D-6E. Similarly, if the PCA 26 is in contact with the vacuum seal 40B and the vacuum source 36 is on, the region 43 (i.e., area within the interior of the vacuum seal 40B) defines the area of vacuum pressure that is applied to a center region of the PCA 26; as the vacuum pressure increases in magnitude, the seal 40B also compresses in height. See the compression of vacuum seal 40B in FIGS. 6D-6E. As such, this allows the PIBA 22 and the PCA 26 to come into close contact and ultimately settles at a hard-stop height that is optimal for the Pogo segment PS, as well as the strike bars 25/27.

The latching system is located inside the vacuum zone and positioned between the spring-pin modules. There are two parts to the latching system. As mentioned previously, the strike bars 25/27 make up the first half of the system—these are mounted to the PIBA 22 and PCA 26, and provide a surface to apply a pulling force on either board assemblies. The second part of the system is the sliding latch plate 30. This plate 30 is only engaged once the vacuum force has pulled the PIBA 22 and PCA 26 assemblies into position. Once the plate is engaged vacuum pressure is removed—this allows the PIBA 22 and PCA 26 to be held together solely by the L-shaped projections 30A/30B on the latch plate 30. By removing the vacuum, this eliminates any fluctuations that normally occur in the vacuum that would cause improper electrical contact.

The vacuum system comprises the vacuum source 36, the couplings 36A/36B, and the valve seals 40A/40B. The mechanical system comprises the air source 34, the air cylinder actuator 32, the air cylinder switch 38, the latch plate 30 and the strike bars 25/27.

Although operation of the invention 20 may involve a mixture of automatic and manual control (e.g., switch 38 is shown as a manual switch), the preferred operation is via a controller 21 (e.g., a microcontroller, FIG. 1) that is coupled to the vacuum source 36 and to the switch 38 (as a solid state switch rather than a manual switch). It should be understood, though, that the key aspect of the present invention 20 is the combination of the vacuum system and the mechanical system, whether these systems are automatically-controlled or manually-controlled. As such, the controller 21 line to the switch 38 and the vacuum source 36 are shown hatched.

The sequence of operation after the TIA 24 is installed on the prober headplate PH is, as shown in FIGS. 6A-6E, as follows:
(1) The operator loads the PIBA 22 and the PCA 26 into place, whereby these assemblies placed into contact with their respective vacuum seals 40A and 40B, respectively. See FIG. 6A for placement of the PIBA 22 against the vacuum seal 40A and see FIGS. 6B-6C for placement of the PCA 26 against the vacuum seal 40B;
(2) The operator or a remote system (not shown, e.g., a tester or prober) instructs the controller 21 to start Pogo “docking” sequence;
(3) Following that, the controller 21 activates the vacuum source 36 to expose the PIBA 22 and the PCA 26 to the vacuum, thereby pulling the PIBA 22 downward (see arrows 42 in FIG. 6C) against the vacuum seal 40A and pulling the PCA 26 upward (see arrows 44 in FIG. 6C) against the vacuum seal 40B which compresses these seals; see FIG. 6D; this action also positions the L-shaped projections 30A/30B into their respective receptacles 25A/27A in strike bars 25/27;
(4) The controller 21 monitors vacuum pressure until it reaches/surpasses a target pressure (e.g., approximately 25 inHg);
(5) The controller 21 then activates the switch 38 which causes the air cylinder actuator 32 to extend in the direction 39 (see FIG. 6D), thereby causing the L-shaped projections 30A/30B to also move in the direction 39 (see FIG. 6D) which “latches” or “locks” the latch plate 30 so that the PIBA 22 and PCA 26 are now in a stable electrical contact while eliminating or otherwise minimizing deflections of the PCA 26;
(6) The controller 21 then releases the vacuum pressure and monitors until the vacuum pressure is mostly restored to atmospheric pressure (e.g., <5 inHg); and
(7) The controller notifies the operator or remote system that the docking sequence is complete.

Conversely, to separate the PIBA 22 and PCA 26, a vacuum force is applied. The latch plate 30 can move only when the spring force from the Pogo segment PS are no longer acting on the latch plate 30.

### REFERENCE CHARACTERS

PS Pogo segment
20 Hybrid vacuum-assisted mechanical latch system
21 controller
22 Probe-Interface-Board (PIB)
24 Test-Interface-Assembly (TIA)
25 strike bars on PIBA 22
25A L-shaped receptacles on strike bar 25
26 Probe Card Assembly (PCA)
27 strike bars on the PCA
27A L-shaped receptacles on strike bar 27
28 Prober Headplate
30 latch plate
30A upper L-shaped projections
30B lower L-shaped projections
32 actuator (e.g., air cylinder actuator)
32A first valve
32B second valve
34 power source (e.g., air source)
36 vacuum source
36A vacuum coupling
36B vacuum coupling
38 manual switch
39 direction of latch plate and actuator
40A upper vacuum seal
40B lower vacuum seal
41 vacuum pressure region within the vacuum seal 40A
42 downward direction of PIBA 22 due to application of vacuum
43 vacuum pressure region within the vacuum seal 40B
44 upward direction of PCA 26 due to application of vacuum

While the invention has been described in detail and with reference to specific examples thereof, it will be apparent to one skilled in the art that various changes and modifications can be made therein without departing from the spirit and scope thereof.

What is claimed is:

1. A hybrid vacuum-assisted mechanical latch system for use in automatic test equipment (ATE) for semiconductor wafers wherein a test interface assembly used therein includes spring-loaded electrical contacts that present spring forces that must be overcome in order to achieve stable electrical contact between a probe interface board assembly and a probe card assembly while minimizing or eliminating deflections of portions of the probe card assembly, said system comprising:
a probe interface board assembly (PIBA) having a plurality of strike bars on a first side of said PIBA, each strike bar having a first plurality of receptacles configured for receiving a first plurality of projections therein;
a probe card assembly (PCA) having a second plurality of strike bars on a first side of said PCA, each strike bar having a second plurality of receptacles configured for receiving a second plurality of projections therein;
a test interface assembly (TIA) having a displaceable latch plate therein, said latch plate comprising said first plurality of projections on an upper edge and said second plurality of projections on a lower edge, opposite said upper edge; and
a vacuum system, in fluid communication with said TIA, for temporarily applying a vacuum to said PIBA to position said first plurality of projections within said first plurality of receptacles and applying said temporary vacuum to said PCA to position said second plurality of projections within said second plurality of receptacles, and wherein said latch plate is displaced to lock said first plurality of projections within said first plurality of receptacles and to lock said second plurality of projections within said second plurality of receptacles such that said PIBA and said PCA are placed into a fixed position with stable electrical contact, by providing a compression force that overcomes the spring forces, thereby permitting non-vibrational operation for ATE testing once said vacuum is removed.

2. The system of claim 1 wherein said projections are L-shaped projections.

3. The system of claim 1 further comprising an actuator coupled to said latch plate, said actuator coupled to said latch plate for displacing said latch plate.

4. The system of claim 3 wherein said actuator is an air cylinder actuator that is coupled to a source of pressurized air via a switch.

5. The system of claim 4 wherein said vacuum system comprising a vacuum source.

6. The system of claim 5 further comprising a controller that is coupled to said vacuum source and said switch, said controller controlling the activation of said vacuum source and said switch for controlling the activation of said actuator.

7. The system of claim 4 wherein said switch is a manual switch.

8. The system of claim 1 further comprising a first vacuum seal on said first side of said TIA that defines a closed region for applying the vacuum to said PIBA.

9. The system of claim 8 further comprising a second vacuum seal on said second side of said TIA that defines a closed region for applying the vacuum to said PCA.

10. The system of claim 1 wherein said compression forces are in the range of 700 lbf-2200 lbf.

11. A method for supporting automatic test equipment (ATE) testing of semiconductor wafers wherein spring-loaded electrical contacts used in a testing interface assembly that present spring forces that must be overcome in order to achieve stable electrical contact between a probe interface board assembly and a probe card assembly while minimizing or eliminating deflections of portions of the probe card assembly, said method comprising:
providing a probe interface board assembly (PIBA) having a plurality of strike bars on a first side of said PIBA, each strike bar having a first plurality of receptacles configured for receiving a first plurality of projections therein;
providing a probe card assembly (PCA) having a second plurality of strike bars on a first side of said PCA, each strike bar having a second plurality of receptacles configured for receiving a second plurality of projections therein;
providing a test interface assembly (TIA) having a displaceable latch plate therein, said latch plate comprising said first plurality of projections on an upper edge and said second plurality of projections on a lower edge, opposite said upper edge;
positioning said PIBA into contact with a first side of said TIA and positioning said PCA into contact with a second side, opposite said first side, of said TIA;
temporarily applying a vacuum from first side of said TIA to said PIBA to position said first plurality of projections within said first plurality of receptacles and also temporarily applying said vacuum from said second side of said TIA to said PCA to position said second plurality of projections within said second plurality of receptacles;
displacing said latch plate to lock said first plurality of projections within said first plurality of receptacles and to lock said second plurality of projections within said second plurality of receptacles such that said PIBA and said PCA are placed into a fixed position by providing a compression force that overcomes the spring forces; and
removing said vacuum to thereby permit non-vibrational operation for ATE testing.

12. The method of claim 11 wherein said projections are L-shaped projections.

13. The method of claim 11 wherein said step of providing said test interface assembly (TIA) comprises coupling an actuator to said latch plate for displacing said latch plate.

14. The method of claim 13 wherein said actuator is an air cylinder actuator and wherein said step of providing said test interface assembly (TIA) comprises coupling said air cylinder actuator to a source of pressurized air via a switch.

15. The method of claim 14 wherein said step of temporarily applying a vacuum comprises coupling said TIA to a vacuum source.

16. The method of claim 15 further comprising coupling a controller to said vacuum source and to said switch, said controller controlling the activation of said vacuum source and said switch for controlling the activation of said actuator.

17. The method of claim 14 wherein said switch is a manual switch.

18. The method of claim 11 wherein said step of providing said test interface assembly (TIA) comprises positioning a first vacuum seal on said first side of said TIA that defines a closed region for applying the vacuum to said PIBA.

19. The method of claim 18 wherein said step of providing said test interface assembly (TIA) comprises positioning a second vacuum seal on said second side of said TIA that defines a closed region for applying the vacuum to said PCA.

20. The method of claim 11 wherein said compression force is in the range of 700 lbf-2200 lbf.
